(19) United States
(12) Patent Application Publication
(10) Pub. No.: US 2007/0112538 A1
(43) Pub. Date: May 17, 2007

(54) Concurrent control of semiconductor parametric testing

(75) Inventors: Sergey A. Velichko, Boise, ID (US); Robert G. Blunn, Boise, ID (US); Michael J. Dorough, Meridian, ID (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/651,139

(22) Filed: Jan. 9, 2007

Related U.S. Application Data
(63) Continuation of application No. 09/834,751, filed on Apr. 13, 2001.

(51) Int. Cl. G01R 31/00

(52) U.S. Cl. 702/117

(57) ABSTRACT

An automated semiconductor parametric test system has a control module that is operable to concurrently control both operation of semiconductor test equipment and operation of parametric test instrumentation. A state oscillator module is controlled by the control module, and further may be operated by the control module in some embodiments to control the state of other system modules in synchronization with other system events. A parametric test equipment module facilitates control of the semiconductor parametric test equipment, and a test instrumentation module facilitates control of the parametric test instrumentation.

### RELATED APPLICATIONS

This application is a continuation of U.S. application Ser. No. 09/834,751, filed Apr. 13, 2001, which is incorporated herein by reference.

### FIELD OF THE INVENTION

The invention relates generally to testing semiconductors, and more specifically to fault-tolerant concurrent control of semiconductor parametric tests.

### BACKGROUND OF THE INVENTION

Fabrication of semiconductors typically comprises many steps, including creation of a silicon wafer, deposition of various materials onto the wafer, ion implantation into the wafer, etching material applied to the wafer, and other similar processes. These processes are used to create the electronic components and connections on the wafer that form a useful electronic circuit.

As these processes are performed on the wafer, the wafer may be subjected to parametric testing. Parametric testing involves testing the electronic parameters of the circuitry on the wafer, such as by applying current or voltage, and by measuring resistance, capacitance, current, voltage, or other such electrical parameters. These tests are used to ensure that a fabricated structure on the semiconductor meets the specifications and requirements of the semiconductor manufacturer, and falls within acceptable tolerances.

Parametric testing can take place during the fabrication process to ensure that each stage of fabrication is successful, and is usually performed on the completed wafer to ensure that each completed circuit on the wafer is functional and meets specified performance criteria.

This parametric testing is typically performed with a parametric test system, which comprises several parts. Such systems may be capable of loading a wafer from a wafer tray to a wafer chuck, which is then positioned by a wafer positioner to a proper alignment under a test pin. Once the equipment has properly loaded and moved the wafer into position, parametric test instrumentation systems are initialized, and operated to apply electrical signals, heat, and other stimuli as needed to the wafer. The test instrumentation also then takes measurements of parameters, such as impedance and current or voltage measurement, and the test system analyzes and records the results of the parametric tests.

Although parametric testing is typically used to verify the parameters or performance of production semiconductors, such testing can also be critical in investigating the usability or performance characteristics of new materials or new circuit structures. A wide variety of tests, including resistance, capacitance, transistor characteristic, thermal characteristic, and other tests enable characterization of these new materials and circuits, as well as verification of performance in a production environment.

Testing a single wafer can involve tens of thousands of measurements per wafer, with dozens of wafers per manufacturing lot or wafer tray loaded for test. Because this results in literally millions of parametric tests and measurements that must be performed per wafer lot, the time that such testing requires is an important factor in the productivity of a wafer or semiconductor fabrication facility.

It is therefore desirable to operate a semiconductor parametric test system that minimizes the time required to perform semiconductor parametric testing.

### BRIEF DESCRIPTION OF THE FIGURES

FIG. 1 shows a timing diagram illustrating a typical sequence of events in a prior art parametric testing system.

FIG. 2 shows a timing diagram illustrating a time sequence of events, consistent with an embodiment of the present invention.

FIG. 3 illustrates the components of a parametric in-line test system, consistent with an embodiment of the present invention.

FIGS. 4A-C illustrate the progression of states during a lot run superstate in an embodiment of the present invention.

FIGS. 5A-B illustrate operation of the state oscillator module of an embodiment of the present invention.

FIG. 6 shows generally the states comprising the lot run superstate of an embodiment of the present invention.

FIG. 7 shows generally the states comprising the abort superstate of an embodiment of the present invention.

FIG. 8 illustrates components comprising a control system of an embodiment of the present invention.

### DETAILED DESCRIPTION

In the following detailed description of sample embodiments of the invention, reference is made to the accompanying drawings which form a part hereof, and in which is shown by way of illustration specific sample embodiments in which the invention may be practiced. These embodiments are described in sufficient detail to enable those skilled in the art to practice the invention, and it is to be understood that other embodiments may be utilized and that logical, mechanical, electrical, and other changes may be made without departing from the spirit or scope of the present invention. The following detailed description is, therefore, not to be taken in a limiting sense, and the scope of the invention is defined only by the appended claims.

The present invention provides an automated semiconductor parametric test system, and has a control module that is operable to concurrently control both operation of semiconductor test equipment and operation of parametric test instrumentation. Further embodiments of the control module also comprise concurrent management of test data, such as analysis of parametric test results or loading of wafer test parameters. Concurrent control enables realization of a reduction in the amount of time taken to perform semiconductor parametric testing.

The control module is in some embodiments of the invention implemented in software executing on a computerized system, and is operable to control a state oscillator module. The state oscillator module of some embodiments of the invention is operable to control the state of other system modules, and further may be operated by the control module in some embodiments such as to control the state of other system modules in synchronization with other system events

Further embodiments of the present invention comprise a parametric test equipment module operable to facilitate control of the semiconductor parametric test equipment, such as wafer loader, a wafer positioner, a wafer chuck, a wafer tray loader, or a prober. A test instrumentation module may also be utilized to facilitate control of the parametric test instrumentation, such as a test probe or a semiconductor test parameter module.

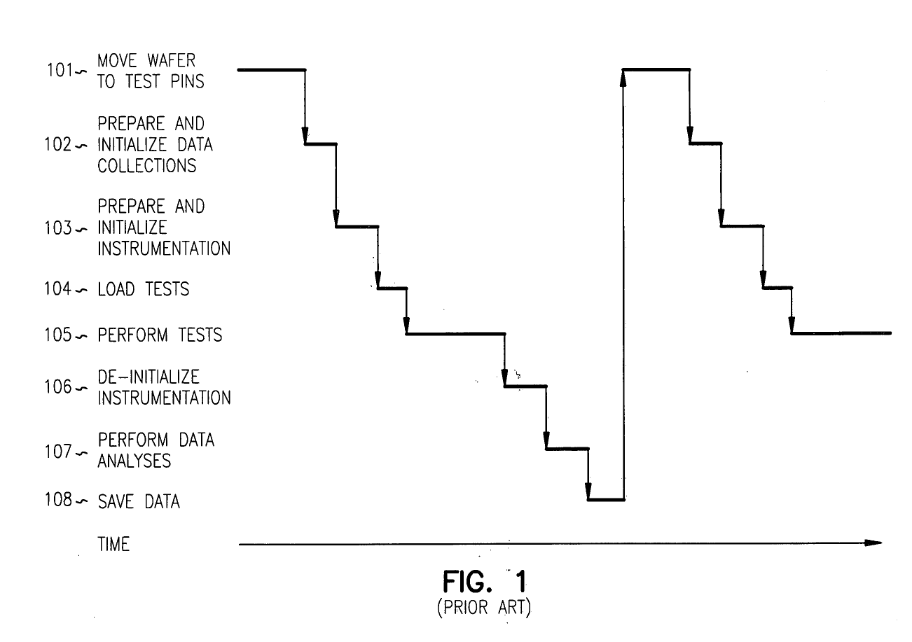

FIG. 1 illustrates a typical sequence of events in a prior art parametric testing system. Once a wafer is loaded into a wafer chuck, the wafer chuck is positioned by a wafer positioner to a proper alignment with the test pins at 101. At 102, initialization of the data collection system is performed, and initialization of the parametric test instrumentation is subsequently performed at 103. Tests specific to the wafer under test are loaded at 104, and the tests are then performed at 105. At 106, the test instrumentation is de-initialized. This deinitialization comprises activities such as removing applied voltages or currents from the test pins, and is critical to prevent damaging the wafer as the pins are later positioned at another test site on the wafer.

At 107, data analysis is performed, such as statistical analysis and tolerance verification, and this data is saved at 108. Next, the wafer is again moved to apply a different portion of the wafer to the test pins, and the steps are repeated for the new test site as is illustrated by the progression shown in FIG. 1. This illustration of such a prior art system shows that a significant amount of time is taken for a number of steps performed in series for each test site used in parametric testing.

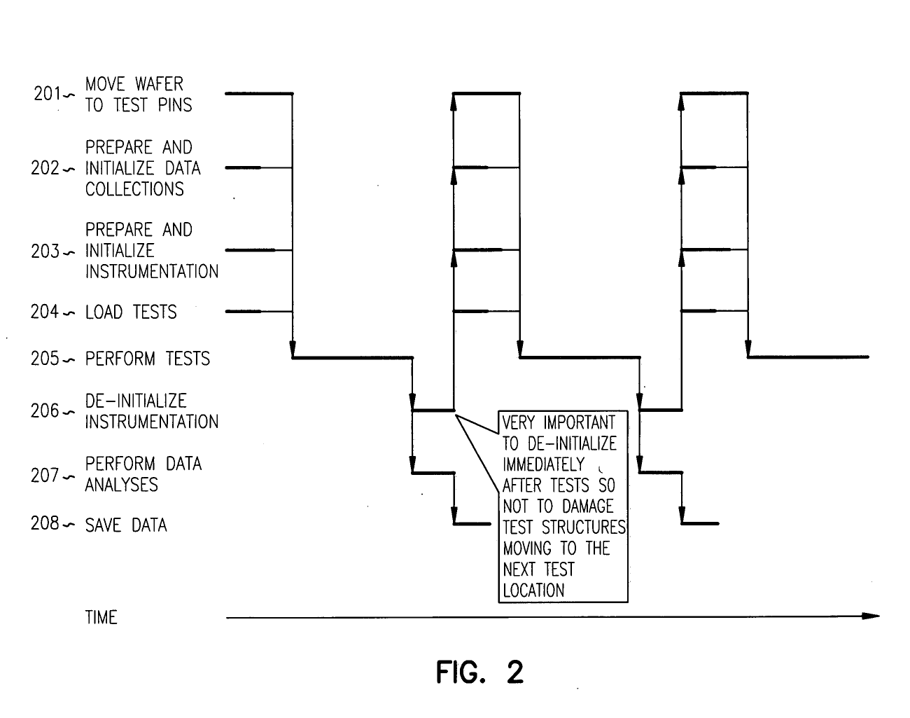

FIG. 2 illustrates how one embodiment of the invention improves on the system and method utilized in conjunction with prior art FIG. 1. At 201, the wafer under test is again moved into position under the test pins. But, data collections are prepared and initialized concurrently at 202, and test instrumentation is initialized at 203 and semiconductor-specific tests are loaded at 204 at the same time. Performing these tasks in parallel results in significant time savings, increasing the productivity of such a wafer test system.

The semiconductor parametric tests are performed at 205, and upon completion the parametric test instrumentation is deinitialized at 206. Concurrent with the deinitialization, data analysis is performed at 207. The results of the data analysis are recorded at 208, as the test system moves the wafer under test to a new location and applies the test pins, prepares and initializes the data collection system, prepares and initializes the test instrumentation system, and loads tests for the next site under test.

As FIG. 2 illustrates, the ability of the present invention to perform multiple functions concurrently can significantly reduce the time needed to complete parametric testing of a wafer lot. Preliminary application of an embodiment of the invention to one specific example application has reduced wafer lot test times from 20.5 hours to 16.25 hours, making the system of the present invention 26% more efficient than the previously utilized system.

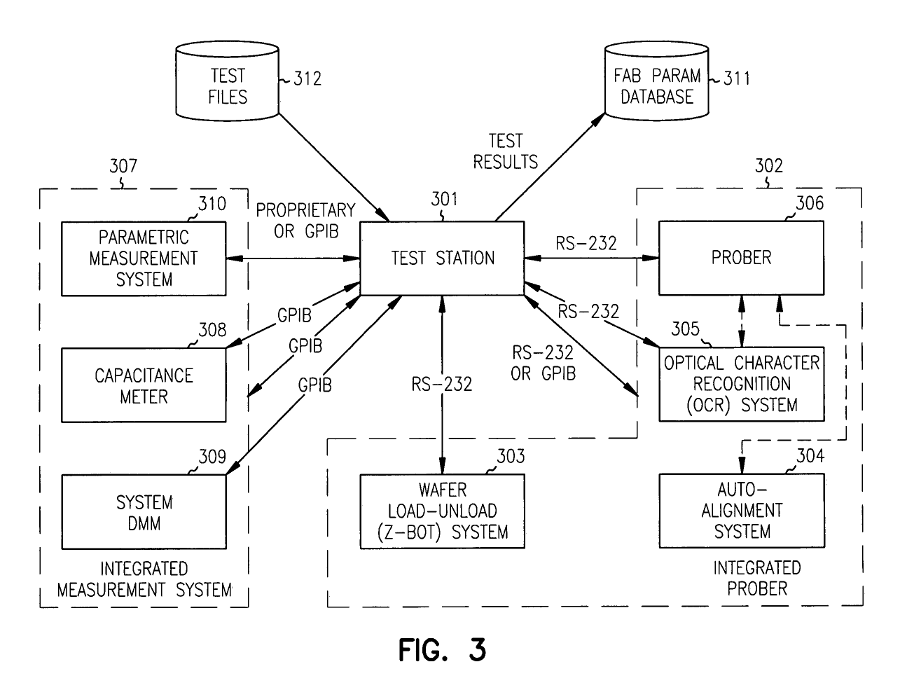

FIG. 3 shows how the components comprising one embodiment of a typical parametric tester are assembled. A test station 301 is connected to a prober equipment system 302, which provides wafer movement capability. The prober 302 comprises a wafer loader 303, an auto-alignment system for aligning wafers at 304, an optical character recognition system 305, and a probe assembly 306. The probe assembly 306 comprises test pins, as well as a wafer chuck and mover system that coordinates with the auto-alignment system 304 as shown.

Parametric test instrumentation includes the integrated measurement system shown at 307, which comprises a capacitance meter 308 and digital multimeter 309. The integrated measurement system also comprises a parametric measurement system 310, which is operable to perform additional measurements and tests.

The test station also is operably connected to test files 312, which stores parameters for the wafer under test. These parameters include definition of the tests to be performed on the wafer, and of the data to be collected during the wafer tests. Parameter database 311 stores information including in some embodiments of the invention the results of the tests, as well as statistics summarizing the test results.

The parametric test system illustrated in FIG. 3 shows how the test instrumentation system of one embodiment of the invention comprises a test instrumentation system and a prober equipment system. These systems in some embodiments of the invention may be integrated with each other in ways not reflected in the drawing; for example, the wafer chuck of the integrated prober part of the semiconductor test equipment system may be heated or cooled by the integrated measurement system or another part of the parametric instrumentation system. The operation of these various systems is controlled and coordinated in some embodiments by a test station controller, which can be pictured for purposes of FIG. 3 as the test station 301.

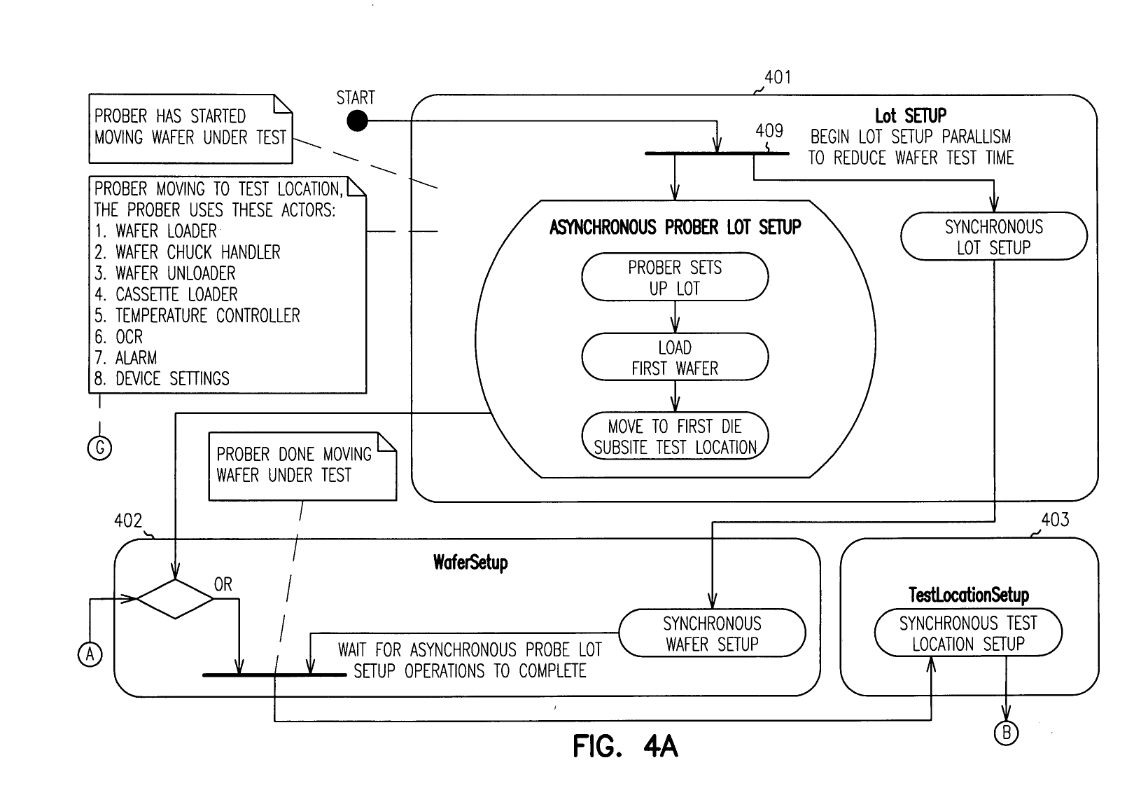

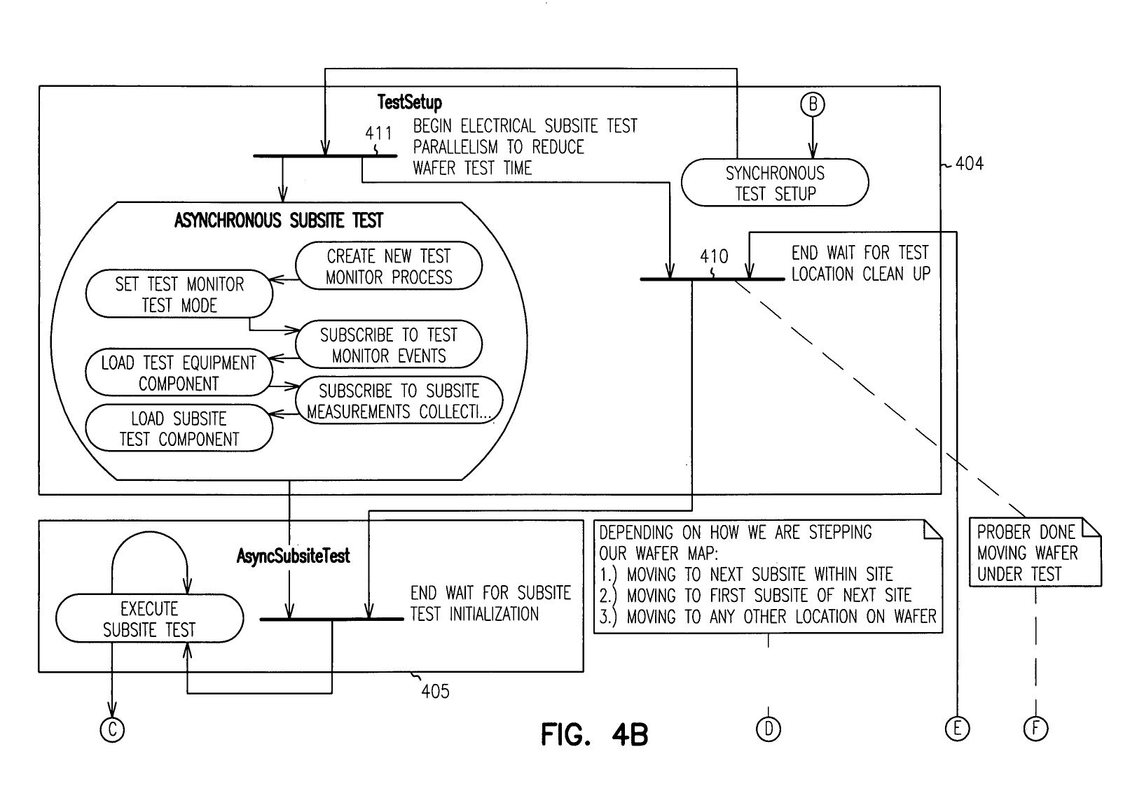

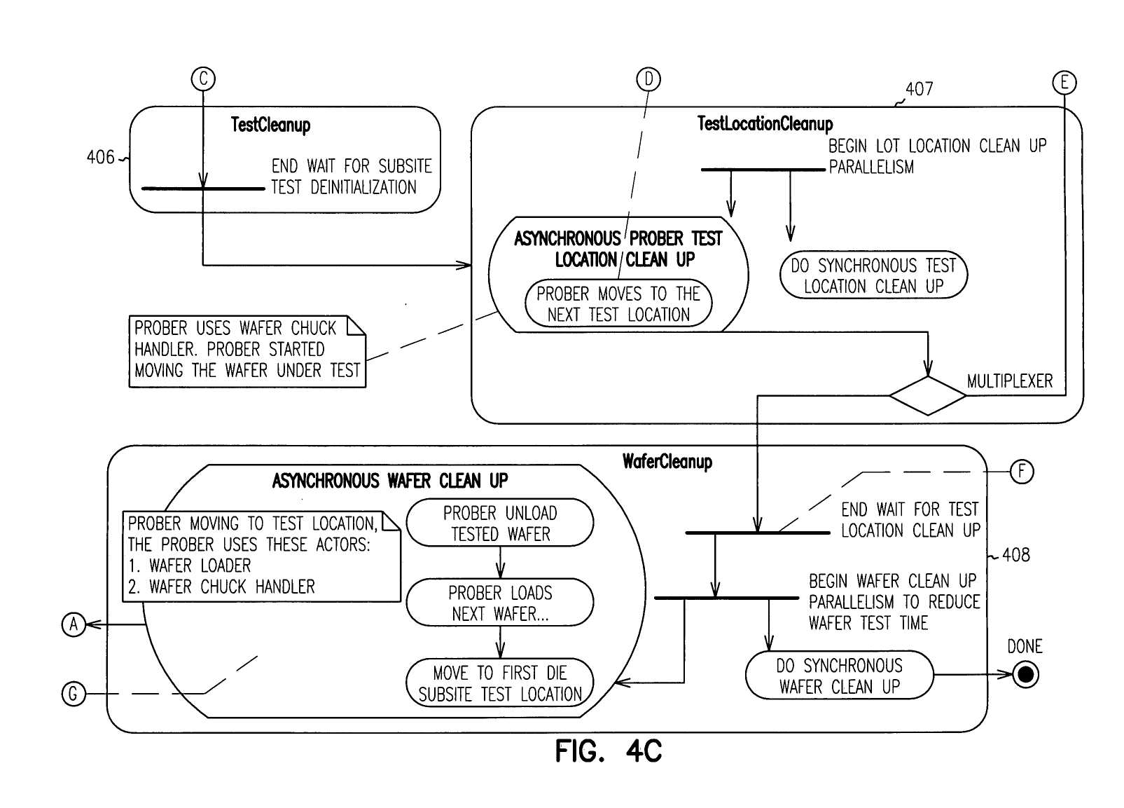

FIGS. 4A-C illustrate the progression of states of one embodiment of the present invention when the parametric test system is in a lot run superstate. Progression through the states of FIGS. 4A-C include both a more detailed version of the elements shown in FIG. 2, plus lot setup and other functions.

At 401, the wafer lot under test is set up. This comprises loading the first wafer from the lot into the chuck and positioning the wafer loader, also known as setting up the wafer prober. Concurrent with setting up the wafer prober equipment to perform the tests, data collection, instrumentation, and test-specific data are loaded or initialized in the test instrumentation.

Once the instrumentation is initialized and the wafer handling equipment has loaded the first wafer and moved it to an appropriate test position, the wafer setup occurs at 402. Wafer setup in various embodiments of the invention comprises elements such as loading test parameters specific to the wafer under test, and initializing other test instrumentation systems or modules.

After the wafer setup has been completed at 402, the test location setup is performed at 403. This comprises in various embodiments of the invention events such as loading test parameters for that particular test site, initializing the test pins, creating or initializing data structures to hold the test results, and other activities. After the test location setup is complete, the actual test process for that site is set up at 404. This test setup comprises events such as creating a new test monitor process, setting the test monitor mode, subscribing to or monitoring test monitor system events, loading test equipment control modules, subscribing to subsite parametric measurement systems, and loading other subsite test components.

After this subsite test initialization is complete, the subsite test is performed at 405. Upon completion of the subsite parametric test, the test cleanup is performed at 406. This cleanup or deinitialization comprises activity such as removing voltage or current from the test pins, turning off application of heat or cold to the wafer under test, and performing other functions to avoid damaging the wafer under test before moving to the next subsite for test.

After the test cleanup, data analysis is performed for the subsite that has been tested, and the prober system moves the wafer to the next test location or subsite. This test location occurs at 407, and upon its completion a new subsite test is begun at 404.

Once all subsites on a wafer have been tested, the test system proceeds to wafer cleanup at 408. This wafer cleanup comprises concurrently performing equipment functions such as unloading the tested wafer and loading a new wafer, and positioning the new wafer for the first new test. At the same time, instrumentation functions such as wafer data analysis are performed in some embodiments, including such functions as statistical or tolerance analysis.

FIGS. 4A-C also illustrate that synchronization of concurrent events is an element of this embodiment of the present invention. This figure conforms to the Unified Modeling Language standard, and so the solid horizontal bars indicate synchronization points. For example, at 409, operation flow proceeds concurrently to synchronous lot setup and asynchronous prober lot setup, as shown in lot set up 401. Similarly, at 410, operation flow proceeds to the subsite test 405 only after prober test location cleanup and movement are complete and the next test location setup is finished at 411.

This synchronization of states is an important element of concurrent operation of various components and modules of the test system, and ensures that the concurrent operations proceed in a timely manner under the direction of the system controller. Use of semaphores, mutexes, monitors, or other structures are implemented in various embodiments of the invention to facilitate synchronization between concurrent operations. Race situations in which separate concurrent paths proceed without regulation are thereby prevented, enabling synchronization of operations in complex flow sequences such as the example illustrated in FIG. 4.

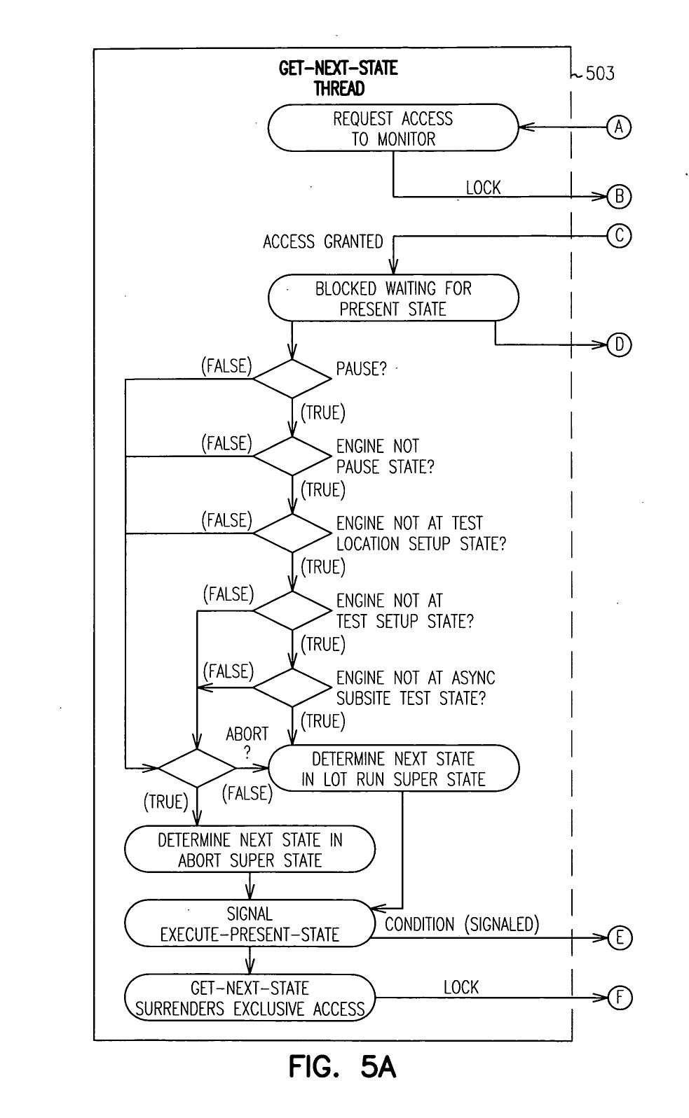

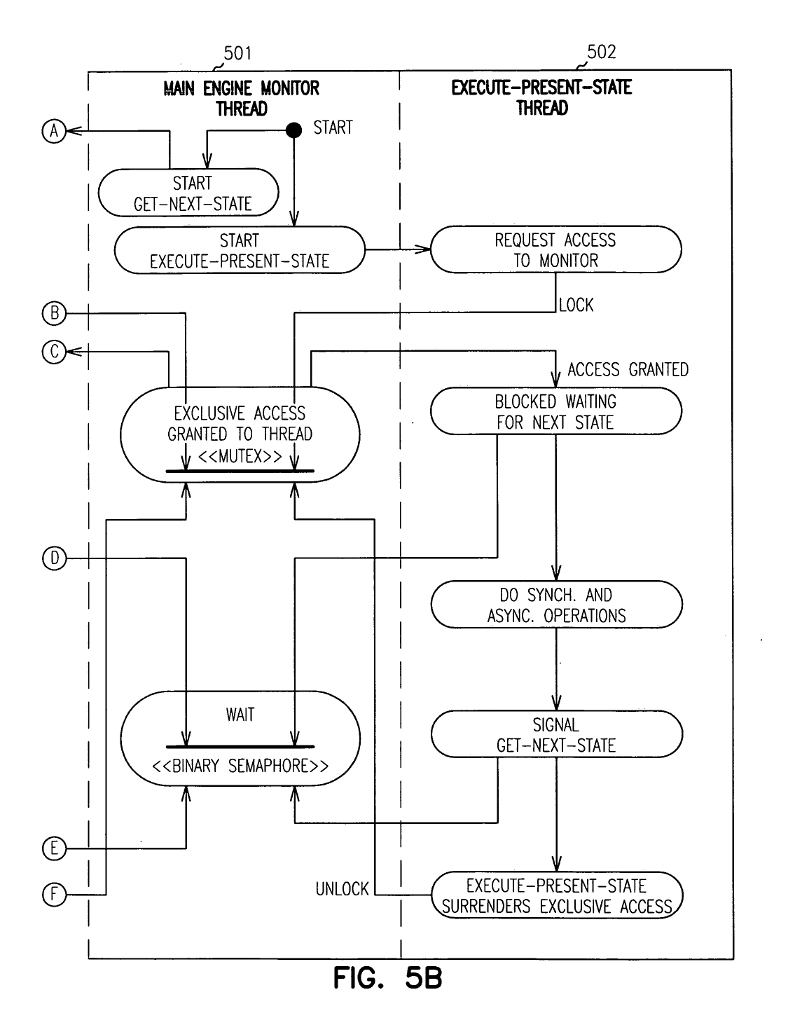

Control of the state of the test system is handled in some embodiments of the present invention by a state oscillator module, one variation of which is explained here in conjunction with FIGS. 5A-B. The state oscillator module proceeds through the states of a superstate, controlling progression through the states to ensure a new state is ready but is not entered until a previous state is complete. The state oscillator module also prevents interruption of states in some embodiments, such as preventing removing a test pin with current applied when a test abort superstate is started to avoid damaging the wafer under test.

The state oscillator module also allows regulation of asynchronous events such as an abort, pause, or continue state, which may be introduced by the user or by the system. A user may abort or pause a test if the user detects that a wafer test is not proceeding as anticipated, in the case of mechanical failure, or for other reasons. Also, the test system of some embodiments will detect when such events occur, and will pause or abort the test based on detection of such conditions.

A main engine monitor thread at 501 controls both execution of the present state and acquisition of the next state. The execute present state thread shown at 502 requests exclusive access from the monitor thread, and proceeds to do synchronous and asynchronous test operations if exclusive access is granted. Upon completion of the operations, the get-next-state signal is sent, and the execute present state thread at 502 surrenders exclusive access. Access is then granted to the get next state thread at 503, which determines the next state in the lot run or abort superstates as appropriate, and signals the execute present state thread with the next state. The get next state thread then surrenders access to the main engine monitor thread, which grants access to the execute present state thread to execute the next state.

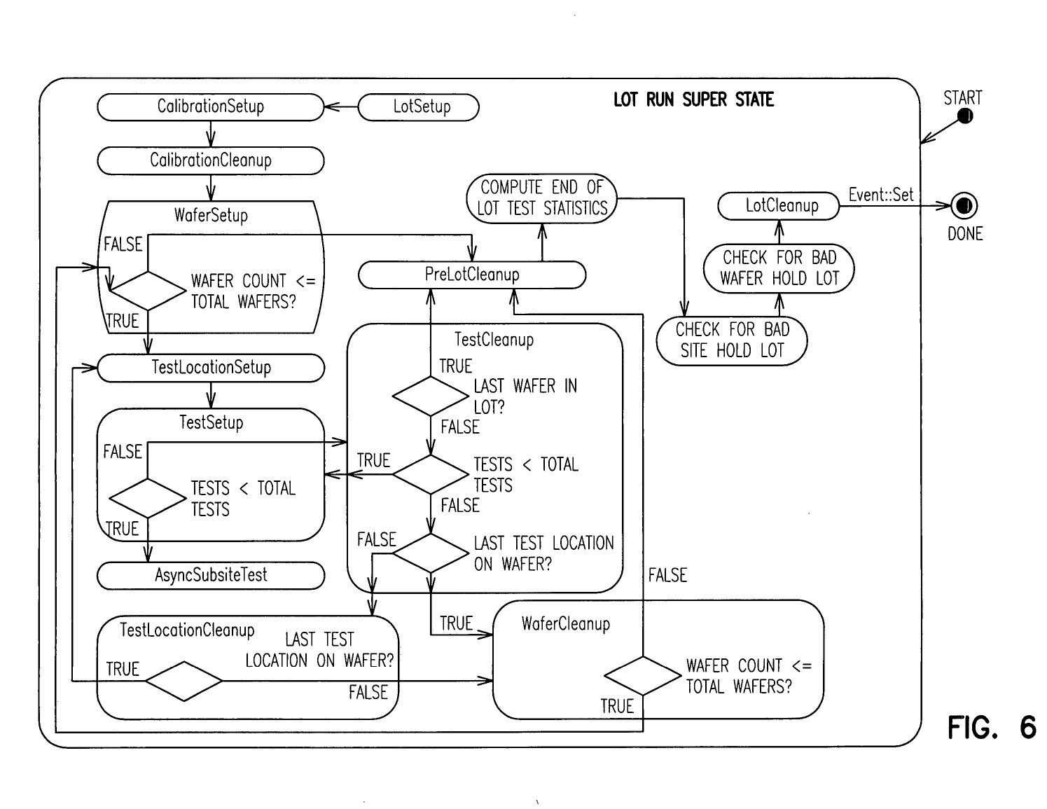

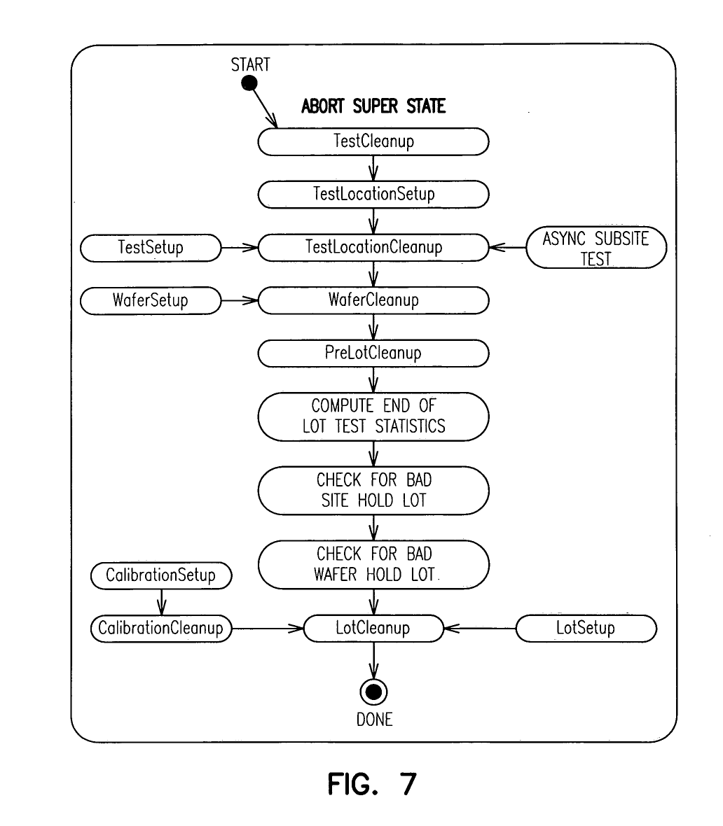

A pause superstate may be entered as shown in the get next state thread 503 of FIGS. 5A-B, from which the system may either continue by entering a non-pause state such as the lot run or abort superstates. FIG. 6 illustrates in greater detail the steps associated with one embodiment of a lot run superstate, and FIG. 7 similarly shows steps associated with an embodiment of an abort superstate.

Such a system provides synchronous transition of both instrumentation and equipment systems within a parametric test system, and provides a robust state management system that is capable of safely handling pause or abort states. The wafer under test is thereby protected, as an abort or pause are executed only after the execute present state thread has completed operations in an orderly manner and surrendered control to the main engine monitor thread. This ensures that a system is not paused or aborted in an undesired state, such as with current applied to test pins, and so protects the wafer under test from damage as a result of a poorly controlled pause or abort.

Further embodiments of the invention also include an emergency abort superstate, in which execution of the current state is suspended and a deinitialization sequence is executed immediately. While such an emergency abort does not allow the current state to finish, it does attempt to prevent damage to the wafer under test by rapid deinitialization of the test instrumentation systems.

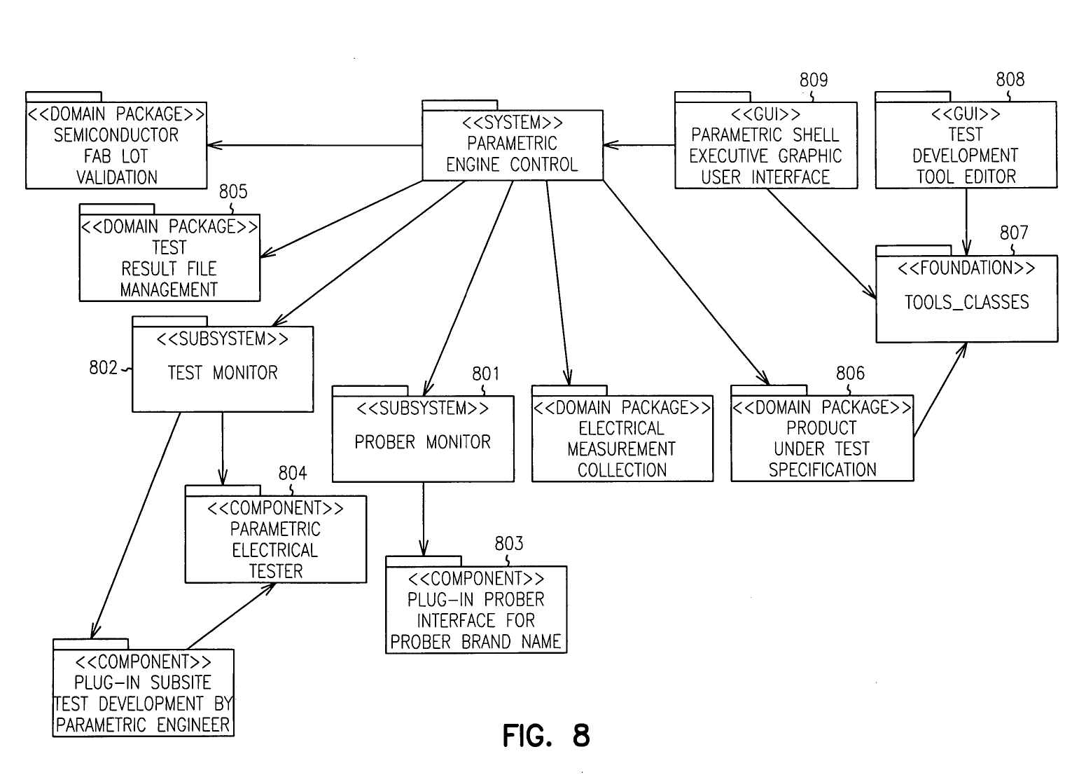

FIG. 8 illustrates generally an overview of the components comprising one embodiment of a control system for a parametric tester. The controller comprises various monitoring subsystems such as a prober monitor 801 and a test monitor 802, which provide the test system an interface to hardware components such as to the prober equipment 803 and parametric test instrumentation 804. Various domain packages provide the controller system with other functions, such as test result file management at 805 and specification of the product under test at 806. Some domain packages such as the product under test specification 806 may utilize foundation tool classes 807, which are also here used by the graphical user interfaces for the test development tool 808 and the executive interface 809 to provide a functional interface to defined test system operations.

By utilizing reusable software components to provide an interface to the test equipment and test instrumentation in some embodiments of the invention, the task of creating tests or other operations that interface with these hardware components is greatly simplified. Such a control approach also facilitates use of different hardware components, as only the interface software component need be replaced for use with different equipment.

These various components enable concurrent control of the example embodiments of the present invention described above, thereby making operation of the parametric test system equipment and instrumentation more time efficient. Embodiments of the invention incorporating concurrent operation of various equipment operations and instrumentation operations are described, along with a description of a state oscillator and system for synchronization of operations. The state oscillator and synchronization features facilitate the control module's concurrent control of the various equipment and instrumentation hardware components of a parametric test system, and enable operation of select embodiments of the present invention discussed herein.

Although specific embodiments have been illustrated and described herein, it will be appreciated by those of ordinary skill in the art that any arrangement which is calculated to achieve the same purpose may be substituted for the specific embodiments shown. This application is intended to cover any adaptations or variations of the invention. It is intended that this invention be limited only by the claims, and the full scope of equivalents thereof.

We claim:

1. An automated semiconductor parametric test system, comprising:
a control module comprising at least one electric circuit, the control module operable to control concurrent operation of semiconductor test equipment and operation of parametric test instrumentation.

2. The automated semiconductor parametric test system of claim 1, wherein the control module is implemented in software executable within the automated semiconductor parametric test system.

3. The automated semiconductor parametric test system of claim 1, wherein the control module is implemented in electronic hardware.

4. The automated semiconductor parametric test system of claim 1, wherein the semiconductor test equipment comprises at least one of a wafer loader, a wafer positioner, a wafer chuck, a wafer tray loader, and a prober.

5. The automated semiconductor parametric test system of claim 1, wherein the parametric test instrumentation comprises at least one parametric test instrument having at least one test probe or test receptacle.

6. The automated semiconductor parametric test system of claim 1, wherein operation of the parametric test instrumentation comprises operation of a test equipment module, the test equipment module operable to facilitate control of the semiconductor test equipment.

7. The automated semiconductor parametric test system of claim 1, wherein operation of the parametric test instrumentation comprises operating a parametric test instrumentation module, the parametric test instrumentation module operable to facilitate control of the parametric test instrumentation.

8. The automated semiconductor parametric test system of claim 1, wherein operation of the parametric test instrumentation comprises operating a semiconductor test parameter module.

9. The automated semiconductor parametric test system of claim 1, wherein the control module is further operable to concurrently manage test data.

10. The automated semiconductor parametric test system of claim 1, wherein the control module is further operable to provide fault-tolerant control of the test state via a state oscillator module, the state oscillator module operable to control the state of other system modules.

11. The automated semiconductor parametric test system of claim 10, wherein the state oscillator module changes the state of other system modules.

12. The automated semiconductor parametric test system of claim 10, wherein operation of the state oscillator module is controlled in synchronization with other system events by the control module.

13. The automated semiconductor parametric test system of claim 10, wherein the state oscillator module is operable to control module states within the system during operational superstates including an abort superstate, a pause superstate, and a lot run superstate; each superstate comprising an ordered sequence of states.

14. An automated semiconductor parametric test system, comprising:
a control module comprising at least one electric circuit, the control module operable to control concurrent operation of semiconductor test equipment and operation of parametric test instrumentation;
a state oscillator module, the state oscillator module controlled by the control module and operable to control the state of other system modules;
a parametric test equipment module, the parametric test equipment module operable to facilitate control of the semiconductor parametric test equipment; and
a test instrumentation module, the test instrumentation module operable to facilitate control of the parametric test instrumentation.

15. An automated semiconductor parametric test system, comprising:
a control module operable to control concurrent motion of semiconductor test equipment and operation of parametric test instrumentation, the control module implemented in software executing on a computerized system comprising at least one electric circuit;
a state oscillator module, the state oscillator module controlled by the control module and operable to control the state of other system modules in synchronization with other system events;
a parametric test equipment module, the parametric test equipment module operable to facilitate control of the semiconductor parametric test equipment, wherein the semiconductor parametric test equipment comprises at least one of a wafer loader, a wafer positioner, a wafer chuck, a wafer tray loader, and a prober; and
a test instrumentation module, the test instrumentation module operable to facilitate control of the parametric test instrumentation, wherein the parametric test instrumentation comprises at least one of a test probe and a semiconductor test parameter module.

16. An automated semiconductor parametric test system controller, comprising:
a control module comprising at least one electric circuit, the control module operable to control concurrent operation of semiconductor test equipment and operation of parametric test instrumentation.

17. The automated semiconductor parametric test system controller of claim 16, wherein the semiconductor test equipment comprises at least one of a wafer loader, a wafer positioner, a wafer chuck, a wafer tray loader, and a prober.

18. The automated semiconductor parametric test system controller of claim 16, wherein the parametric test instrumentation comprises at least one parametric test instrument having at least one test probe or test receptacle.

19. The automated semiconductor parametric test system controller of claim 16, wherein operation of the parametric test instrumentation comprises operation of a test equipment module, the test equipment module operable to facilitate control of the semiconductor test equipment.

20. The automated semiconductor parametric test system controller of claim 16, wherein operation of the parametric test instrumentation comprises operating a parametric test instrumentation module, the parametric test instrumentation module operable to facilitate control of the parametric test instrumentation.

21. The automated semiconductor parametric test system controller of claim 16, wherein operation of the parametric test instrumentation comprises operating a semiconductor test parameter module.

22. The automated semiconductor parametric test system controller of claim 16, wherein the control module is further operable to concurrently manage test data.

23. The automated semiconductor parametric test system controller of claim 16, wherein the control module is further operable to provide fault-tolerant control of the test state via a state oscillator module, the state oscillator module operable to control the state of other system modules.

24. The automated semiconductor parametric test system controller of claim 23, wherein the state oscillator module changes the state of other system modules.

25. The automated semiconductor parametric test system controller of claim 23, wherein operation of the state oscillator module is controlled in synchronization with other system events by the control module.

26. The automated semiconductor parametric test system controller of claim 23, wherein the state oscillator module is operable to control module states within the system during operational superstates including an abort superstate, a pause superstate, and a lot run superstate; each superstate comprising an ordered sequence of states.

27. An automated semiconductor parametric test system controller, comprising:
a control module comprising at least one electric circuit, the control module operable to control concurrent operation of semiconductor test equipment and operation of parametric test instrumentation;
a state oscillator module, the state oscillator module controlled by the control module and operable to control the state of other system modules;
a parametric test equipment module, the parametric test equipment module operable to facilitate control of the semiconductor parametric test equipment; and
a test instrumentation module, the test instrumentation module operable to facilitate control of the parametric test instrumentation.

28. An automated semiconductor parametric test system controller, comprising:
a control module operable to control concurrent motion of semiconductor test equipment and operation of parametric test instrumentation, the control module implemented in software executable on the semiconductor parametric test system controller, wherein the semiconductor parametric test system controller comprises at least one electric circuit;
a state oscillator module, the state oscillator module controlled by the control module and operable to control the state of other system modules in synchronization with other system events;
a parametric test equipment module, the parametric test equipment module operable to facilitate control of the semiconductor parametric test equipment, wherein the semiconductor parametric test equipment comprises at least one of a wafer loader, a wafer positioner, a wafer chuck, a wafer tray loader, and a prober; and
a test instrumentation module, the test instrumentation module operable to facilitate control of the parametric test instrumentation, wherein the parametric test instrumentation comprises at least one of a test probe and a semiconductor test parameter module.

29. A machine-readable medium with instructions stored thereon, the instructions readable and executable by a computerized system, and the instructions when executed operable to cause the computerized system to control a semiconductor parametric test system by:
controlling via a control module concurrent operation of semiconductor test equipment and operation of parametric test instrumentation.

30. The machine-readable medium of claim 29, wherein the control module is implemented in software.

31. The machine-readable medium of claim 29, wherein the control module is implemented in electronic hardware.

32. The machine-readable medium of claim 29, wherein the semiconductor test equipment comprises at least one of a wafer loader, a wafer positioner, a wafer chuck, a wafer tray loader, and a prober.

33. The machine-readable medium of claim 29, wherein the parametric test instrumentation at least one parametric test instrument having at least one test probe or test receptacle.

34. The machine-readable medium of claim 29, wherein operation of the parametric test instrumentation comprises operation of a test equipment module, the test equipment module operable to facilitate control of the semiconductor test equipment.

35. The machine-readable medium of claim 29, wherein operation of the parametric test instrumentation comprises operating a parametric test instrumentation module, the parametric test instrumentation module operable to facilitate control of the parametric test instrumentation.

36. The machine-readable medium of claim 29, wherein operation of the parametric test instrumentation comprises operating a semiconductor test parameter module.

37. The machine-readable medium of claim 29, wherein the control module is further operable to concurrently manage test data.

38. The machine-readable medium of claim 29, wherein the control module is further operable to provide fault-tolerant control of the test state via a state oscillator module, the state oscillator module operable to control the state of other system modules.

39. The machine-readable medium of claim 38, wherein the state oscillator module changes the state of other system modules.

40. The machine-readable medium of claim 38, wherein operation of the state oscillator module is controlled in synchronization with other system events by the control module.

41. The machine-readable medium of claim 38, wherein the state oscillator module is operable to control module states within the system during operational superstates including an abort superstate, a pause superstate, and a lot run superstate; each superstate comprising an ordered sequence of states.

42. A machine-readable medium with instructions stored thereon, the instructions readable and executable by a computerized system, and the instructions when executed operable to cause the computerized system to control a semiconductor parametric test system by:
controlling via a control module concurrent operation of semiconductor test equipment and operation of parametric test instrumentation;
controlling the state of at least one other system module via a state oscillator module, the state oscillator module controlled by the control module;
providing control of the semiconductor parametric test equipment via operation of a parametric test equipment module; and
providing control of the parametric test instrumentation via operation of a test instrumentation module.

43. A machine-readable medium with instructions stored thereon, the instructions readable and executable by a computerized system, and the instructions when executed operable to cause the computerized system to control a semiconductor parametric test system by:
controlling via a control module implemented in software and executing on a computerized system, concurrent motion of semiconductor test equipment and operation of parametric test instrumentation;
controlling the state of at least one other system module via a state oscillator module, the state oscillator module controlled by the control module and operable to control the state of other system modules in synchronization with other system events;
providing control of the semiconductor parametric test equipment via operation of a parametric test equipment module, wherein the semiconductor parametric test equipment comprises at least one of a wafer loader, a wafer positioner, a wafer chuck, a wafer tray loader, and a prober; and
providing control of the parametric test instrumentation via operation of a test instrumentation module, wherein the parametric test instrumentation comprises at least one of a test probe and a semiconductor test parameter module.
